(19) United States
(12) Patent Application Publication
(10) Pub. No.: US 2025/0283206 A1
(43) Pub. Date: Sep. 11, 2025

(54) MASK, DEPOSITION APPARATUS, AND METHOD OF MANUFACTURING MASK

(71) Applicant: Samsung Display Co., LTD., Yongin-si (KR)

(72) Inventors: EUISUK JUNG, Yongin-si (KR); TAE JOON KIM, Yongin-si (KR); SOON-HWAN SO, Yongin-si (KR); CHOULWON MIN, Yongin-si (KR); WONSEON YU, Yongin-si (KR); YOJUNG YIM, Yongin-si (KR)

(21) Appl. No.: 19/050,361

(22) Filed: Feb. 11, 2025

(30) Foreign Application Priority Data
Mar. 11, 2024 (KR) 10-2024-0033705

(51) Int. Cl. C23C 14/04; C23C 14/24

(52) U.S. Cl. CPC C23C 14/042; C23C 14/24

(57) ABSTRACT

A mask includes a first layer defining a first opening, and a second layer disposed on the first layer, where the second layer includes a deposition pattern having a reverse-tapered shape in a cross-sectional view. The deposition pattern defines second openings overlapping the first opening in a plan view, and the second layer includes silicon having a crystal orientation of <100>.

This application claims priority to Korean Patent Application No. 10-2024-0033705, filed on Mar. 11, 2024, and all the benefits accruing therefrom under 35 U.S.C. § 119, the content of which in its entirety is herein incorporated by reference herein.

### BACKGROUND

### 1. Field

Embodiments relate to a mask, a deposition apparatus including the mask, and a method of manufacturing the mask.

### 2. Description of the Related Art

A display device is typically formed by stacking a plurality of layers such as a light emitting layer, a metal layer, or the like. A deposition process may be performed to form the plurality of layers of the display device. The deposition process may be performed by closely contacting a mask that has a same pattern as a pattern of the light emitting layer, the metal layer, or the like on a target substrate on which deposition is to be performed. In this case, an evaporated material sprayed from a deposition source may be deposited on the target substrate through the mask.

### SUMMARY

Embodiments provide a mask with improved reliability.

Embodiments provide a deposition apparatus including the mask.

Embodiments provide a method of manufacturing the mask.

A mask according to an embodiment of the disclosure includes a first layer defining a first opening, and a second layer disposed on the first layer, where the second layer includes a deposition pattern having a reverse-tapered shape in a cross-sectional view. In such an embodiment, the deposition pattern defines second openings overlapping the first opening in a plan view, and the second layer includes silicon having a crystal orientation of <100>.

In an embodiment, an angle formed between a surface of the deposition pattern, which is spaced apart from the first layer, and a side surface of the deposition pattern may be about 45° or greater and about 75° or less.

In an embodiment, a width of each of the second openings may be greater than or equal to a thickness of the deposition pattern.

In an embodiment, the first layer may include silicon.

In an embodiment, the mask may further include an insulating layer disposed between the first layer and the second layer.

A deposition apparatus according to an embodiment of the disclosure includes a deposition source which accommodates a deposition material, a mask disposed on the deposition source, where the deposition material passes through the mask, and a stage disposed on the mask, where a target substrate, on which the deposition material is to be deposited, is fixed to the stage. In such an embodiment, the mask includes a first layer defining a first opening, and a second layer disposed on the first layer, where the second layer includes a deposition pattern having a reverse-tapered shape in a cross-sectional view. In such an embodiment, the deposition pattern defines second openings overlapping the first opening in a plan view and, and the second layer includes silicon having a crystal orientation of <100>.

In an embodiment, an angle formed between a surface of the deposition pattern, which is spaced apart from the first layer, and a side surface of the deposition pattern may be about 45° or greater and about 75° or less.

In an embodiment, a width of each of the second openings may be greater than or equal to a thickness of the deposition pattern.

In an embodiment, the first layer may include silicon.

In an embodiment, the mask may further include an insulating layer disposed between the first layer and the second layer.

A method of manufacturing a mask according to an embodiment of the disclosure includes forming a first layer defining a first opening by etching a preliminary first layer, and forming a second layer including a deposition pattern having a reverse-tapered shape in a cross-sectional view by etching a preliminary second layer disposed below the preliminary first layer, where the deposition pattern defines second openings overlapping the first opening in a plan view, and the second layer includes silicon having a crystal orientation of <100>.

In an embodiment, in the forming the second layer, the deposition pattern may be formed so that a surface spaced apart from the first layer of the deposition pattern and a side surface of the deposition pattern form an angle of about 45° or greater and about 75° or less.

In an embodiment, in the forming the second layer, a width of each of the second openings may be formed to be greater than or equal to a thickness of the deposition pattern.

In an embodiment, in the forming the second layer, the preliminary second layer may be etched using an etchant including potassium hydroxide (KOH).

In an embodiment, a concentration of the potassium hydroxide may be about 15 weight percent (wt %) or greater and about 70 wt % or less.

In an embodiment, a temperature of the potassium hydroxide may be about 50° C. or higher and about 100° C. or lower.

In an embodiment, the forming the first layer may include forming an auxiliary pattern defining an auxiliary opening by etching the preliminary first layer.

In an embodiment, the forming the auxiliary pattern may include forming a first sub-opening by etching the preliminary first layer, and forming second sub-openings connected to the first sub-opening by etching the preliminary first layer.

In an embodiment, in the forming the second layer, the auxiliary pattern of the preliminary first layer and the preliminary second layer may be etched simultaneously.

In an embodiment, the method may further include forming an insulating layer by etching a preliminary insulating layer disposed between the first preliminary layer and the second preliminary layer.

In a deposition apparatus according to embodiments of the disclosure, the deposition apparatus may include a mask including silicon. In such embodiments, the mask may include a deposition pattern defining openings and having a reverse-tapered shape in a cross-sectional view. Accordingly, a deposition material that passes through the openings of the mask and is deposited on a target substrate may not be deposited in an area other than a deposition area of the target substrate. Therefore, in embodiments of a display device manufactured using the mask, stains, color mixing, or the like on the display device that may occur when the deposition material is deposited in the area other than the deposition area of the target substrate may be minimized.

In addition, in a method of manufacturing a mask according to embodiments of the disclosure, an etching process of a wafer may be performed sequentially in one direction without any process of turning the wafer over during the etching process of the wafer, such that problems caused by foreign substances or the like that may occur while turning the wafer over during a manufacturing process of the mask may be minimized.

### BRIEF DESCRIPTION OF THE DRAWINGS

FIG. 1 is a cross-sectional view schematically illustrating a deposition apparatus according to an embodiment of the disclosure.

FIG. 2 is a cross-sectional view illustrating a mask included in the deposition apparatus of FIG. 1.

FIGS. 3, 4, 5, 6, 7, 8, and 9 are cross-sectional views illustrating an embodiment of a method of manufacturing the mask of FIG. 2.

FIG. 10 is a cross-sectional view schematically illustrating an embodiment of a display device manufactured using the deposition apparatus of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in more detail with reference to the accompanying drawings. The same reference numerals are used for the same components in the drawings, and any repetitive detailed descriptions of the same components will be omitted or simplified.

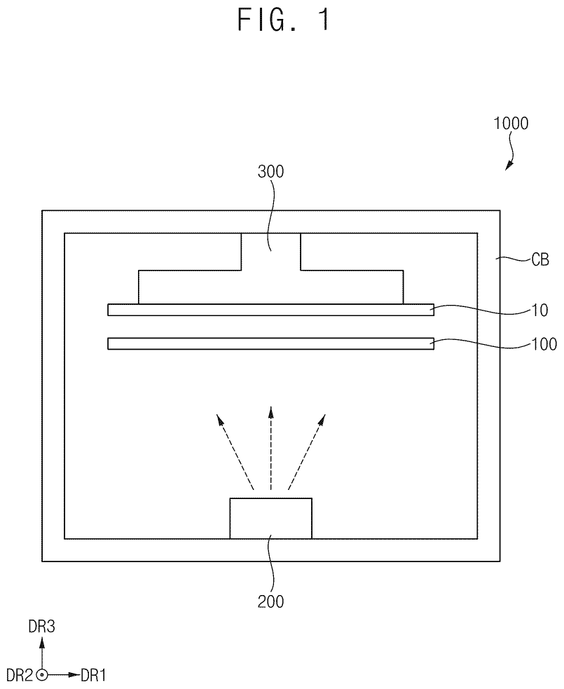

FIG. 1 is a cross-sectional view schematically illustrating a deposition apparatus according to an embodiment of the disclosure.

Referring to FIG. 1, an embodiment of a deposition apparatus 1000 may include a chamber CB, a mask 100, a deposition source 200, and a stage 300.

The deposition apparatus 1000 may deposit a deposition material on a target substrate 10. The target substrate 10 may be a substrate for manufacturing a display device. For example, the target substrate 10 may refer to a display device being manufactured. The target substrate 10 may include a plastic substrate, a glass substrate, a silicon substrate, or the like, and may include at least one layer included in the display device. In an embodiment, for example, the target substrate 10 may include at least one selected from an inorganic layer, an organic layer, or a metal layer.

That is, the deposition apparatus 1000 may be used in a manufacturing process of the display device. For example, the deposition apparatus 1000 may be used in a process of depositing a light emitting layer on the target substrate 10 in the manufacturing process of the display device. However, the disclosure is not limited to thereto, and the deposition apparatus 1000 may be used in various deposition processes in the manufacturing process of the display device.

In an embodiment, the display device may be a micro light emitting diode display device including a micro light emitting diode as a light emitting element. However, the disclosure is not limited thereto, and in another embodiment, the display device may be an organic light emitting diode display device including an organic light emitting diode as a light emitting element.

The chamber CB may provide an inner space in which a deposition process may be performed. In an embodiment, in the chamber CB, an evaporation of evaporating a deposition material and depositing the deposition material on the target substrate 10 may be performed as the deposition process. In such an embodiment, the inner space of the chamber CB may be maintained in a vacuum-state.

Various components that may be used in the deposition process may be disposed inside the chamber CB. In an embodiment, for example, the mask 100, the deposition source 200, and the stage 300 may be disposed inside the chamber CB.

The mask 100 may be parallel to a plane defined by a first direction DR1 and a second direction DR2 intersecting the first direction DR1. For example, the first direction DR1 and the second direction DR2 may be perpendicular to each other. The mask 100 may have a pattern, and the deposition material may be deposited on the target substrate 10 in a pattern corresponding to the pattern. In an embodiment, for example, the mask 100 may include a deposition membrane defining a plurality of openings, and the openings may correspond to deposition areas of the target substrate 10, respectively.

In an embodiment, the mask 100 may include silicon. In an embodiment, for example, the mask 100 may include a silicon wafer (Si wafer), a silicon carbide wafer (SiC wafer), a single crystal silicon wafer (single crystal Si wafer), or the like.

Although FIG. 1 illustrates an embodiment where the mask 100 is spaced apart from the target substrate 10 by a predetermined interval, the disclosure is not limited to thereto. In another embodiment, for example, the mask 100 may be disposed to be in contact with the target substrate 10.

The deposition source 200 may be disposed to face the mask 100. In an embodiment, for example, the deposition source 200 may be disposed below the mask 100, and may be disposed to face the target substrate 10 with the mask 100 interposed therebetween.

The deposition source 200 may accommodate the deposition material. The deposition source 200 may provide the deposition material to the target substrate 10. In an embodiment, for example, the deposition source 200 may vaporize the deposition material, and the vaporized deposition material may be provided toward the target substrate 10. In an embodiment, for example, the deposition material may be provided in a third direction DR3 intersecting each of the first direction DR1 and the second direction DR2. For example, the third direction DR3 may be perpendicular to each of the first direction DR1 and the second direction DR2. In such an embodiment, the vaporized deposition material may pass through the mask 100 and be deposited on the target substrate 10. That is, the deposition material may pass through the openings of the mask 100 and be deposited in the deposition areas on the target substrate 10. In an embodiment, for example, the deposition source 200 may provide an organic material that forms a light emitting layer included in the display device, but the disclosure is not limited thereto.

The stage 300 may be disposed to face the mask 100 in a direction opposite to the deposition source 200. In an embodiment, for example, the stage 300 may be disposed on the mask 100, and may be disposed to face the deposition source 200 with the mask 100 interposed therebetween. The target substrate 10 may be fixed to the stage 300. The target substrate 10 may be fixed to the stage 300 and disposed between the stage 300 and the mask 100.

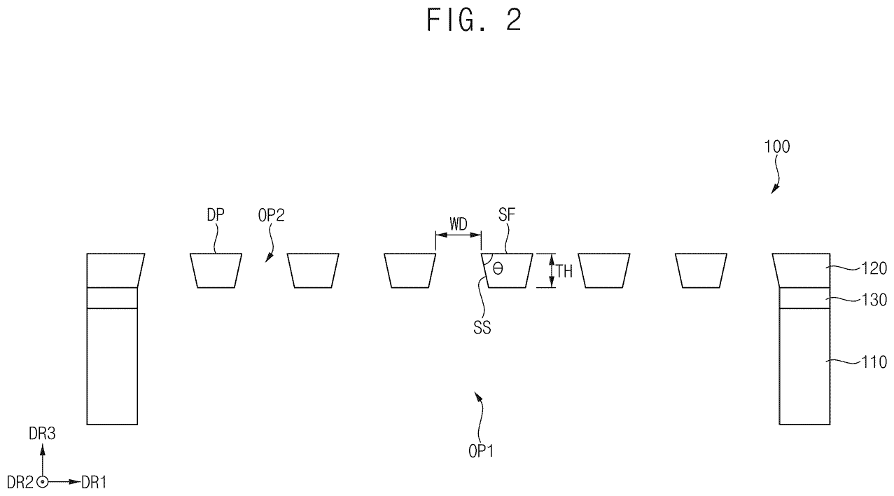

FIG. 2 is a cross-sectional view illustrating a mask included in the deposition apparatus of FIG. 1. For example, FIG. 2 may be a cross-sectional view schematically illustrating a portion of the mask 100.

Referring to FIGS. 1 and 2, an embodiment of the mask 100 may include a first layer 110, a second layer 120, and an insulating layer 130.

In an embodiment, the first layer 110 may include silicon. The first layer 110 may include silicon crystals. In an embodiment, for example, the first layer 110 may include single crystal silicon.

The first layer 110 may define a first opening OP1. The first opening OP1 may be defined through the first layer 110 in the third direction DR3.

The second layer 120 may be disposed on the first layer 110. In an embodiment, the second layer 120 may include silicon. The second layer 120 may include silicon crystals. In an embodiment, for example, the second layer 120 may include single crystal silicon. In an embodiment, the second layer 120 may include silicon having a crystal orientation of <100>. In such an embodiment, the crystal orientation of silicon included in the second layer 120 may be different from or the same as a crystal orientation of silicon included in the first layer 110.

The second layer 120 may define a plurality of second openings OP2. The second layer 120 may include a deposition pattern DP defining the second openings OP2. Each of the second openings OP2 may be defined through the second layer 120 in the third direction DR3. The second opening OP2 may be arranged repeatedly along the first direction DR1 or the second direction DR2, and may be spaced apart from each other. In an embodiment, for example, the second openings OP2 may be disposed in a matrix form along the first direction DR1 and the second direction DR2. In another embodiment, for example, the second openings OP2 may be arranged along either the first direction DR1 or the second direction DR2. The deposition pattern DP may be disposed between the second openings OP2 adjacent to each other. In an embodiment, for example, the deposition pattern DP may have a net shape in a plan view. Here, the phrase “in a plan view” may mean when viewed in the third direction DR3.

The second openings OP2 may overlap the first opening OP1 in a plan view. The second openings OP2 may be connected to the first opening OP1. The first opening OP1 and the second openings OP2 may be defined through the mask 100 in the third direction DR3.

In an embodiment, the deposition pattern DP may have a reverse-tapered shape in a cross-sectional view. That is, a width of the deposition pattern DP may gradually increase in the third direction DR3, and a side surface SS of the deposition pattern DP may be inclined. Here, the width of the deposition pattern DP may be a length of the deposition pattern DP in the first direction DR1. The side surface SS of the deposition pattern DP may be inclined at a constant angle along a thickness direction (i.e., the third direction DR3 or a direction opposite to the third direction DR3) of the deposition pattern DP. Accordingly, an angle at which the deposition material provided in the third direction DR3 toward the target substrate 10 passes through the mask 100 may be limited.

In an embodiment, an angle θ formed between a surface SF spaced apart from the first layer 110 of the deposition pattern DP and the side surface SS of the deposition pattern DP may be about 45° or greater and about 75° or less. In an embodiment, for example, the angle θ may be about 50° or greater and about 60° or less. In an embodiment, for example, the angle θ may be about 53° or greater and about 57° or less. In such embodiments, the angle θ may be adjusted in a way such that the deposition material that has passed through the mask 100 is not deposited in an area other than the deposition area of the target substrate 10.

In an embodiment, a width WD of the second opening OP2 may be greater than or equal to a thickness TH of the deposition pattern DP. Here, the width WD of the second opening OP2 may be a length of the second opening OP2 in the first direction DR1, and the thickness TH of the deposition pattern DP may be a length of the deposition pattern DP in the third direction DR3. In other words, a separation distance of the deposition pattern DP in the first direction DR1 defining the second opening OP2 in a cross-sectional view may be greater than or equal to the thickness TH of the deposition pattern DP. In an embodiment, for example, the width WD of the second opening OP2 may be about 4 micrometers (μm) or greater and about 5 μm or less, and the thickness TH of the deposition pattern DP may be about 1 μm or greater and about 4 μm or less, but the disclosure is not limited thereto.

If the thickness TH of the deposition pattern DP is greater than the width WD of the second opening OP2, there may be an area in which the deposition material is not sufficiently deposited among the deposition areas on the target substrate 10. Accordingly, since the width WD of the second opening OP2 is formed to be greater than or equal to the thickness TH of the deposition pattern DP, an area in which the deposition material is not sufficiently deposited among the deposition areas on the target substrate 10 may be minimized.

The insulating layer 130 may be disposed between the first layer 110 and the second layer 120. The insulating layer 130 may include an inorganic material such as silicon oxide (SiOₓ), silicon nitride (SiNₓ), or the like. The insulating layer 130 may define an opening corresponding to the first opening OP1 of the first layer 110. The opening may be defined through the insulating layer 130 in the third direction DR3, and accordingly, the first opening OP1 and the second openings OP2 may be defined through the mask 100.

The deposition apparatus 1000 according to an embodiment of the disclosure may include the mask 100 including the first layer 110 and the second layer 120. The mask 100 may include silicon, and the second layer 120 may include the deposition pattern DP having a reverse-tapered shape in a cross-sectional view. An angle at which the deposition material provided toward the target substrate 10 passes through the mask 100 may be limited by a cross-sectional shape of the deposition pattern DP. Accordingly, the deposition material that passes through the mask 100 and is deposited on the target substrate 10 may not be deposited in an area other than the deposition area of the target substrate 10. Accordingly, stains, color mixing, or the like on a display device that may be caused by the deposition material being deposited in the area other than the deposition area of the target substrate 10 may be effectively prevented, thereby improving display quality of the display device manufactured using the mask 100.

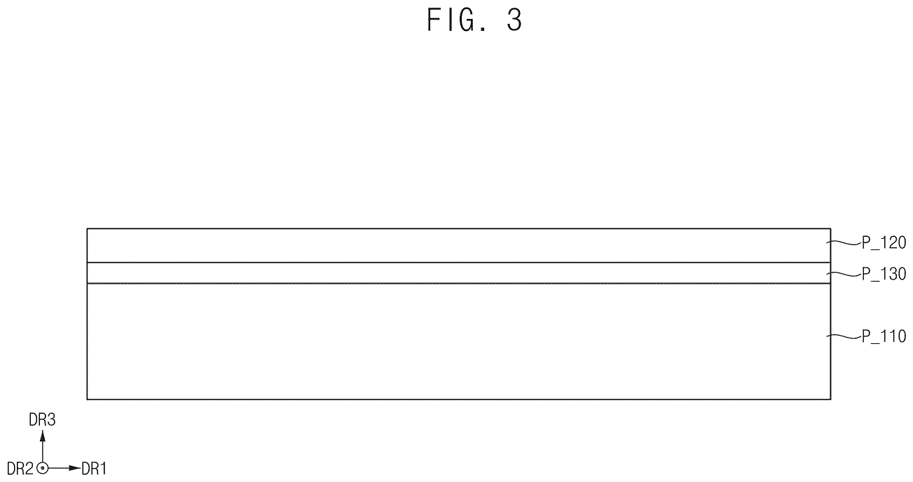

FIGS. 3, 4, 5, 6, 7, 8, and 9 are cross-sectional views illustrating an embodiment of a method of manufacturing the mask of FIG. 2.

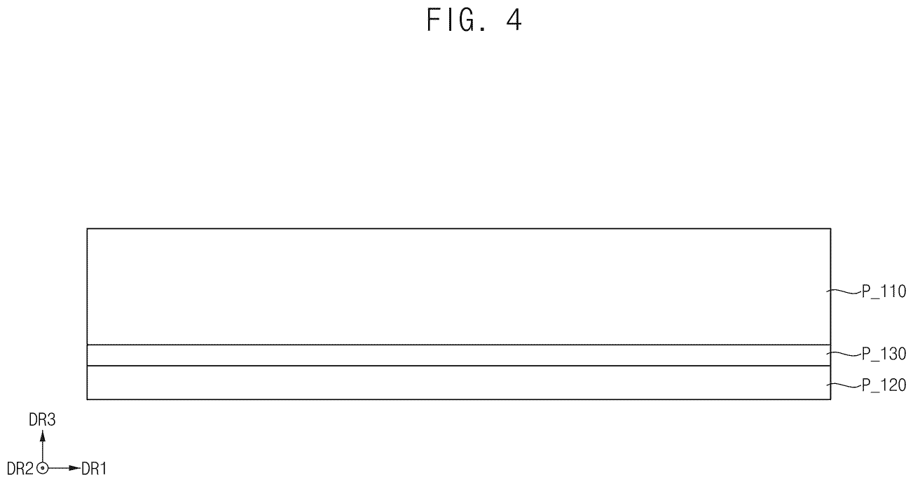

Referring to FIGS. 3 and 4, in an embodiment of a method of manufacturing the mask, a preliminary second layer P_120 and a preliminary insulating layer P_130 may be formed on a preliminary first layer P_110.

In an embodiment, the preliminary first layer P_110 may include silicon. The preliminary first layer P_110 may include silicon crystals. In an embodiment, for example, the preliminary first layer P_110 may include single crystal silicon.

The preliminary second layer P_120 may be disposed on the preliminary first layer P_110. In an embodiment, the preliminary second layer P_120 may include silicon. The preliminary second layer P_120 may include silicon crystals. In an embodiment, for example, the preliminary second layer P_120 may include single crystal silicon. In an embodiment, the preliminary second layer P_120 may include silicon having a crystal orientation of <100>. In such an embodiment, the crystal orientation of silicon included in the preliminary second layer P_120 may be different from or the same as a crystal orientation of silicon included in the preliminary first layer P_110.

The preliminary insulating layer P_130 may be disposed between the preliminary first layer P_110 and the preliminary second layer P_120. The preliminary insulating layer P_130 may include an inorganic material such as silicon oxide, silicon nitride, or the like.

Each of the preliminary first layer P_110, the preliminary second layer P_120, and the preliminary insulating layer P_130 may be a flat layer parallel to the plane defined by the first direction DR1 and the second direction DR2. The preliminary first layer P_110, the preliminary insulating layer P_130, and the preliminary second layer P_120 may be provided sequentially along the third direction DR3. In an embodiment, for example, a wafer including the preliminary first layer P_110, the preliminary insulating layer P_130, and the preliminary second layer P_120 may be provided. In an embodiment, for example, the wafer may be a silicon on insulator (SOI) wafer.

Thereafter, the wafer including the preliminary first layer P_110, the preliminary insulating layer P_130, and the preliminary second layer P_120 may be turned over. That is, the wafer illustrated in FIG. 3 may be turned over (or turned upside down) as illustrated in FIG. 4. Accordingly, the preliminary second layer P_120, the preliminary insulating layer P_130, and the preliminary first layer P_110 may be sequentially disposed along the third direction DR3. However, the disclosure is not limited thereto, and the wafer including the preliminary first layer P_110, the preliminary insulating layer P_130, and the preliminary second layer P_120 may be prepared or provided in an inverted state as illustrated in FIG. 4.

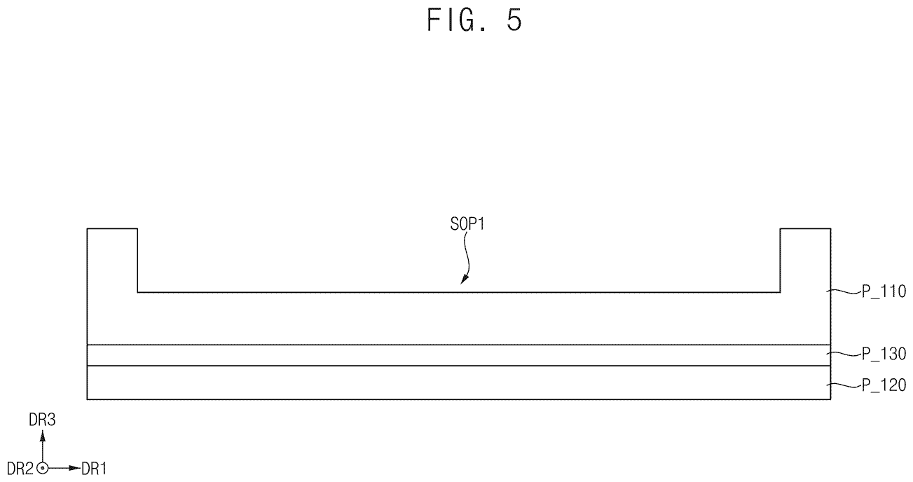

Referring to FIGS. 4 and 5, a portion of the preliminary first layer P_110 may be removed to form a first sub-opening SOP1. The first sub-opening SOP1 may be formed not to entirely through the preliminary first layer P_110.

The first sub-opening SOP1 may be formed by etching from a surface spaced apart from the second preliminary layer P_120 of the preliminary first layer P_110 in a direction opposite to the third direction DR3. In an embodiment, for example, the first sub-opening SOP1 may be formed through a wet etching process, but the disclosure is not limited thereto.

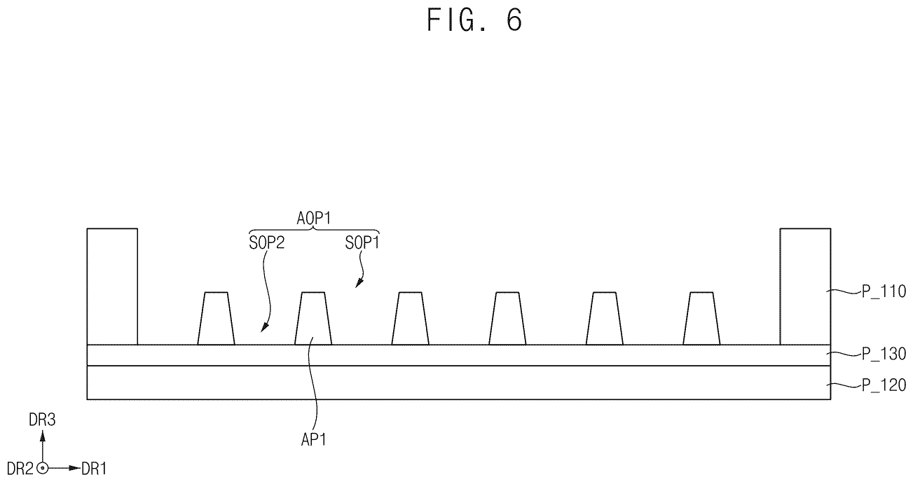

Referring to FIGS. 5 and 6, a portion of the preliminary first layer P_110 may be further removed to form a plurality of second sub-openings SOP2. In addition, the portion of the preliminary first layer P_110 may be removed to form a first auxiliary pattern API defining the second sub-openings SOP2.

The second sub-openings SOP2 may be arranged repeatedly along the first direction DR1 or the second direction DR2, and may be spaced from each other. In an embodiment, for example, the second sub-openings SOP2 may be disposed in a matrix form along the first direction DR1 and the second direction DR2. In another embodiment, for example, the second sub-openings SOP2 may be arranged along either the first direction DR1 or the second direction DR2. The first auxiliary pattern AP1 may be disposed between the second sub-openings SOP2 adjacent to each other. In an embodiment, for example, the first auxiliary pattern AP1 may be formed in a net shape in a plan view.

The second sub-openings SOP2 may be formed by etching from the first sub-opening SOP1 of the first preliminary layer P_110 in the direction opposite to the third direction DR3. In an embodiment, for example, the second sub-openings SOP2 and the first auxiliary pattern AP1 may be formed through a dry etching process, but the disclosure is not limited thereto.

The second sub-openings SOP2 may be connected to the first sub-opening SOP1, and the first sub-opening SOP1 and the second sub-openings SOP2 may form a first auxiliary opening AOP1. The first auxiliary opening AOP1 may define the first auxiliary pattern AP1, and may be formed through the preliminary first layer P_110 in the third direction DR3. That is, the first auxiliary opening AOP1 and the first auxiliary pattern API may be formed in the preliminary first layer P_110 through an etching process.

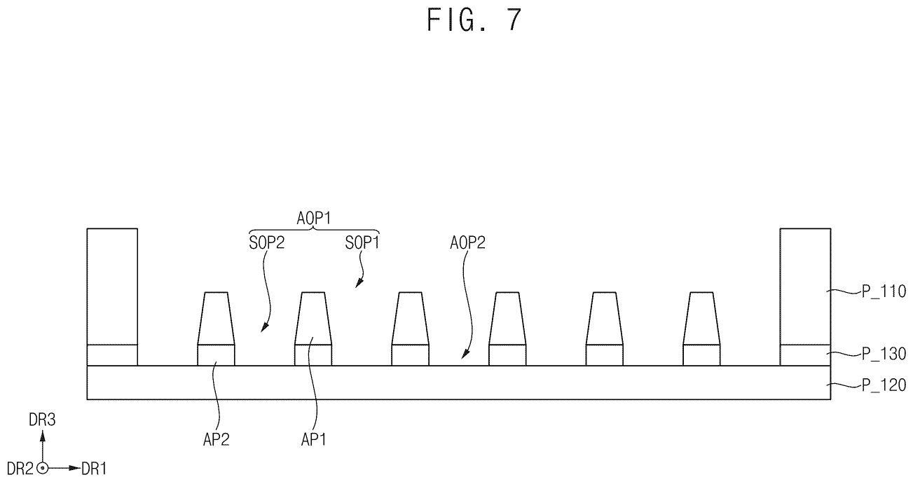

Referring to FIGS. 6 and 7, a portion of the preliminary insulating layer P_130 may be removed to form a plurality of second auxiliary openings AOP2. In addition, the portion of the preliminary insulating layer P_130 may be removed to form a second auxiliary pattern AP2 defining the second auxiliary openings AOP2. Each of the second auxiliary openings AOP2 may be formed through the preliminary insulating layer P_130 in the third direction DR3.

The second auxiliary openings AOP2 may be repeatedly arranged along the first direction DR1 or the second direction DR2, and may be spaced apart from each other. In an embodiment, for example, the second auxiliary openings AOP2 may be disposed in a matrix form along the first direction DR1 and the second direction DR2. In another embodiment, for example, the second auxiliary openings AOP2 may be arranged along either the first direction DR1 or the second direction DR2. The second auxiliary pattern AP2 may be disposed between the second auxiliary openings AOP2 adjacent to each other. In an embodiment, for example, the second auxiliary pattern AP2 may be formed in a net shape in a plan view.

Each of the second auxiliary openings AOP2 may be formed by etching from the first auxiliary opening AOP1 of the preliminary first layer P_110 in the direction opposite to the third direction DR3. The second auxiliary pattern AP2 may be formed by etching in the direction opposite to the third direction DR3 using the first auxiliary pattern AP1 of the preliminary first layer P_110 as a mask. Accordingly, the second auxiliary openings AOP2 may be connected to the first auxiliary opening AOP1, and the second auxiliary pattern AP2 may overlap the first auxiliary pattern AP1 in a plan view. In an embodiment, for example, the second auxiliary openings AOP2 and the second auxiliary pattern AP2 may be formed through a dry etching process, but the disclosure is not limited thereto.

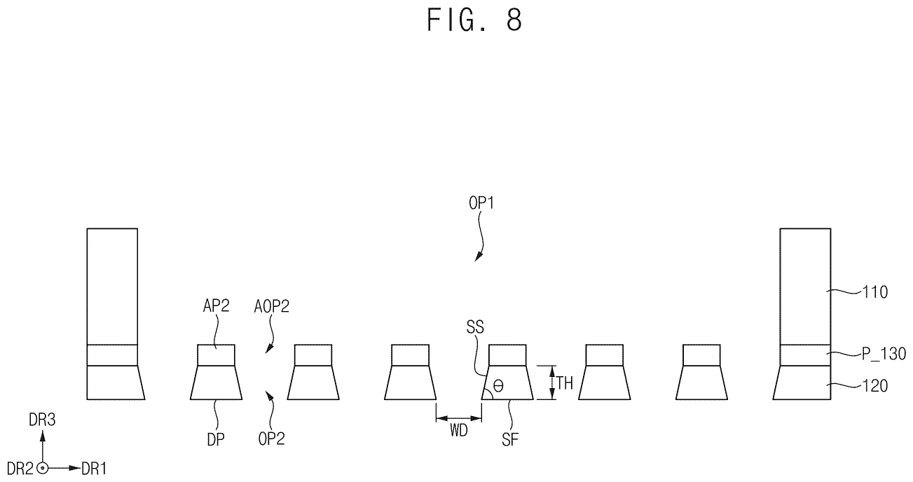

Referring to FIGS. 7 and 8, the first auxiliary pattern AP1 of the preliminary first layer P_110 may be removed to form the first opening OP1, and a portion of the preliminary second layer P_120 may be removed to form the second openings OP2. In addition, the portion of the preliminary second layer P_120 may be removed to form the deposition pattern DP defining the second openings OP2.

Each of the second openings OP2 may be formed by etching from the second auxiliary openings AOP2 of the preliminary insulating layer P_130 in the direction opposite to the third direction DR3. The deposition pattern DP may be formed by etching in the direction opposite to the third direction DR3 using the second auxiliary pattern AP2 of the preliminary insulating layer P_130 as a mask. Accordingly, the second openings OP2 may be connected to the second auxiliary openings AOP2, respectively, and the deposition pattern DP may overlap the second auxiliary pattern AP2 in a plan view. In an embodiment, for example, the second openings OP2 and the deposition pattern DP may be formed through a wet etching process, but the disclosure is not limited thereto.

Accordingly, the first layer 110 defining the first opening OP1 and the second layer 120 including the deposition pattern DP defining the second openings OP2 may be formed. The first opening OP1 may be formed through the first layer 110 in the third direction DR3, and each of the second openings OP2 may be formed through the second layer 120 in the third direction DR3. The first opening OP1 and the second openings OP2 may be connected through the second auxiliary openings AOP2.

In an embodiment, the first auxiliary pattern AP1 of the preliminary first layer P_110 and the portion of the preliminary second layer P_120 may be removed through a same wet etching process as each other. That is, the first layer 110 and the second layer 120 may be formed through a same wet etching process as each other.

In an embodiment, the wet etching process may be performed using an etchant including potassium hydroxide (KOH). In an embodiment, for example, the etchant may include potassium hydroxide, water, and isopropyl alcohol.

In an embodiment, a concentration of the potassium hydroxide may be about 15 weight percent (wt %) or greater and about 70 wt % or less. In an embodiment, for example, the concentration of the potassium hydroxide may be about 30 wt % or greater and about 45 wt % or less. If the concentration of the potassium hydroxide is less than about 30 wt %, a degree of roughness of the deposition pattern DP of the second layer 120 may be relatively increased.

In an embodiment, a temperature of the potassium hydroxide may be about 50° C. or higher and about 100° C. or lower. In an embodiment, for example, the temperature of the potassium hydroxide may be about 70° C. or higher and about 90° C. or lower.

In such an embodiment, time for which the wet etching process is performed may be appropriately changed or controlled depending on the concentration of the potassium hydroxide and the temperature of the potassium hydroxide.

In an embodiment, the deposition pattern DP of the second layer 120 may be formed to have a reverse-tapered (or tapered) shape in a cross-sectional view through the wet etching process. In such an embodiment, the side surface SS of the deposition pattern DP may be formed to be inclined at a constant angle along the thickness direction (i.e., the third direction DR3 or the direction opposite to the third direction DR3) of the deposition pattern DP.

In an embodiment, the deposition pattern DP may be formed in a way such that the surface SF spaced apart from the first layer 110 of the deposition pattern DP and the side surface SS of the deposition pattern DP form the angle θ of about 45° or greater and about 75° or less. In an embodiment, for example, the angle θ may be formed to be about 50° or greater and about 60° or less. In an embodiment, for example, the angle θ may be formed to be about 53° or greater and about 57° or less.

In an embodiment, since the preliminary first layer P_110 may include silicon having the crystal orientation of <100>, when the preliminary first layer P_110 is etched by the etchant including potassium hydroxide, the first layer 110 including the deposition pattern DP in which the surface SF and the side surface SS form the angle θ may be formed. In addition, in an embodiment, the width WD of the second opening OP2 may be formed to be greater than or equal to the thickness TH of the deposition pattern DP.

Although FIG. 8 illustrates an embodiment where the first auxiliary pattern AP1 of the first preliminary layer P_110 is completely removed in the wet etching process of removing a portion of the preliminary first layer P_110 and a portion of the preliminary second layer P_120 to form the first layer 110 and the second layer 120, respectively, the disclosure is not limited thereto. In an embodiment, for example, a portion of the first auxiliary pattern AP1 of the preliminary first layer P_110 may remain without being removed in the wet etching process, and in such an embodiment, an etching process to remove the portion may be further performed. In an embodiment, for example, the portion of the first auxiliary pattern API that remains without being removed may be removed through a dry etching process.

Referring to FIGS. 2, 8, and 9, the second auxiliary pattern AP2 of the preliminary insulating layer P_130 may be removed to form the insulating layer 130. The second auxiliary pattern AP2 may be removed to form the opening corresponding to the first opening OP1, and the first opening OP1 and the second openings OP2 may penetrate the mask 100. In an embodiment, for example, the second auxiliary pattern AP2 may be removed through a dry etching process, but the disclosure is not limited thereto.

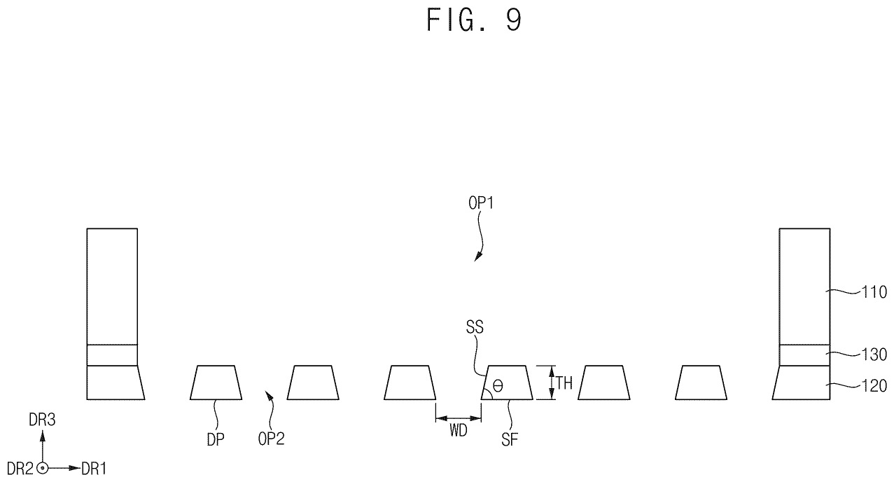

Accordingly, the mask 100 including the first layer 110 defining the first opening OP1, the second layer 120 including the deposition pattern DP defining the second openings OP2, and the insulating layer 130 disposed between the first layer 110 and the second layer 120 may be manufactured. For example, the mask illustrated in FIG. 9 may be used in the deposition process in an inverted state as illustrated in FIG. 2.

In the method of manufacturing the mask 100 according to an embodiment of the disclosure, the etching process of the wafer may be sequentially performed in one direction (e.g., a direction from the first layer 110 to the second layer 120) without any process of turning the wafer over during the etching process may not be performed, such that problems due to foreign substances or the like that may occur while turning the wafer over may be minimized, thereby improving reliability of the process.

In such an embodiment, since the wafer includes the preliminary second layer P_120 including silicon having the crystal orientation of <100>, and the preliminary second layer P_120 is etched through the etchant including potassium hydroxide, the mask 100 including the deposition pattern DP having a reverse-tapered shape in a cross-sectional view may be effectively formed.

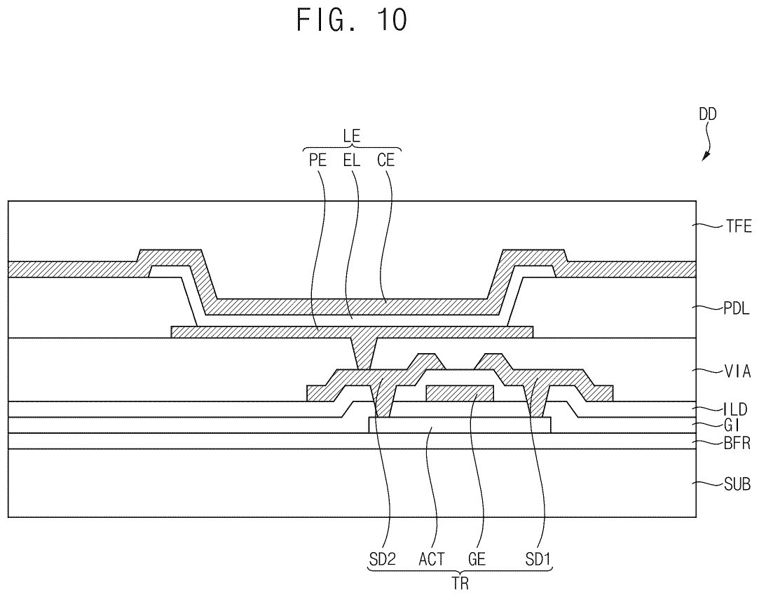

FIG. 10 is a cross-sectional view schematically illustrating an embodiment of a display device manufactured using the deposition apparatus of FIG. 1. For example, FIG. 10 may be a cross-sectional view schematically illustrating a portion of a display device DD manufactured using the deposition apparatus 1000. For example, the display device DD may be formed by cutting the target substrate 10 into a plurality of pieces after the target substrate 10 is manufactured into a plurality of display devices.

Referring to FIGS. 1 and 10, an embodiment of the display device DD may include a base substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE.

In such an embodiment, the transistor TR may include an active pattern ACT, a gate electrode GE, a first electrode SD1, and a second electrode SD2, and the light emitting element LE may include a pixel electrode PE, a light emitting layer EL, and a common electrode CE.

The base substrate SUB may include a transparent material or an opaque material. In an embodiment, for example, the base substrate SUB may include plastic, glass, quartz, silicon, or the like. In an embodiment, for example, the base substrate SUB may include a silicon wafer, a silicon carbide wafer, a single crystal silicon wafer, or the like. These may be used alone or in combination with each other.

The buffer layer BFR may be disposed on the base substrate SUB. The buffer layer BFR may prevent metal atoms, impurities, or the like from diffusing into the transistor TR. In addition, the buffer layer BFR may improve a flatness of a surface of the base substrate SUB, when the surface of the base substrate SUB is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

The active pattern ACT may be disposed on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

The gate insulating layer GI may be disposed on the active pattern ACT, and may cover the active pattern ACT. The gate insulating layer GI may include an inorganic material such as silicon oxide, silicon nitride, silicon oxynitride, or the like. These may be used alone or in combination with each other.

The gate electrode GE may be disposed on the gate insulating layer GI. The gate electrode GE may overlap the channel area of the active pattern ACT in a plan view or when view3ed in a thickness direction of the base substrate SUB. The gate electrode GE may include a metal, an alloy, a conductive metal nitride, a conductive metal oxide, a transparent conductive material, or the like. These may be used alone or in combination with each other.

The interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

The first electrode SD1 and the second electrode SD2 may be disposed on the interlayer insulating layer ILD. The first electrode SD1 may be connected to the source rea of the active pattern ACT through a first contact hole defined in the gate insulating layer GI and the interlayer insulating layer ILD. In addition, the second electrode SD2 may be connected to the drain area of the active pattern ACT through a second contact hole defined in the gate insulating layer GI and the interlayer insulating layer ILD. In an embodiment, for example, each of the first electrode SD1 and the second electrode SD2 may include a metal, an alloy, a conductive metal nitride, a conductive metal oxide, a transparent conductive material, or the like. These may be used alone or in combination with each other.

Accordingly, the transistor TR including the active pattern ACT, the gate electrode GE, the first electrode SD1, and the second electrode SD2 may be disposed on the base substrate SUB.

The via insulating layer VIA may be disposed on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, or the like. These may be used alone or in combination with each other.

The pixel electrode PE may be disposed on the via insulating layer VIA. The pixel electrode PE may be connected to the second electrode SD2 through a contact hole defined in the via insulating layer VIA. The pixel electrode PE may include a metal, an alloy, a conductive metal nitride, a conductive metal oxide, a transparent conductive material, or the like. These may be used alone or in combination with each other. In an embodiment, for example, the pixel electrode PE may operate as an anode.

The pixel defining layer PDL may be disposed on the via insulating layer VIA, and may cover at least a portion of the pixel electrode PE. An opening exposing at least a portion of an upper surface of the pixel electrode PE may be defined in the pixel defining layer PDL. The pixel defining layer PDL may include an inorganic material or an organic material. In an embodiment, for example, the pixel defining layer PDL may include an organic material such as an epoxy resin, a siloxane resin, or the like. In another embodiment, for example, the pixel defining layer PDL may include an inorganic material or an organic material including a light blocking material having a black color.

The light emitting layer EL may be disposed on the pixel electrode PE. The light emitting layer EL may be disposed on the pixel electrode PE exposed by the pixel defining layer PDL. The light emitting layer EL may include an organic material that emits light of a predetermined color.

In an embodiment, the light emitting layer EL may be formed by using the deposition apparatus 1000. In an embodiment, for example, as the target substrate 10 on which the pixel defining layer PDL is formed moves or passes through the deposition apparatus 1000, the light emitting layer EL may be formed. However, the disclosure is not limited thereto, and various thin films included in the display device DD may be formed by using the deposition apparatus 1000.

The common electrode CE may be disposed on the light emitting layer EL. In an embodiment, for example, the common electrode CE may be a plate electrode. The common electrode CE may include a metal, an alloy, a conductive metal nitride, a conductive metal oxide, a transparent conductive material, or the like. These may be used alone or in combination with each other. For example, the common electrode CE may operate as a cathode.

Accordingly, the light emitting element LE including the pixel electrode PE, the light emitting layer EL, and the common electrode CE may be disposed on the base substrate SUB. The light emitting element LE may be electrically connected to the transistor TR.

The encapsulation layer TFE may be disposed on the common electrode CE. The encapsulation layer TFE may protect the light emitting element LE from external oxygen, moisture, or the like. The encapsulation layer TFE may include at least one inorganic layer and at least one organic layer. In an embodiment, for example, the encapsulation layer TFE may have a structure in which inorganic layers and organic layers are alternately stacked.

Embodiments of the disclosure may be applied to a manufacturing process of various display devices. such as display devices for vehicles, ships and aircraft, portable communication devices, display devices for exhibition or information transmission, medical display devices, or the like, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask comprising:
a first layer defining a first opening; and
a second layer disposed on the first layer, wherein the second layer includes a deposition pattern having a reverse-tapered shape in a cross-sectional view,
wherein the deposition pattern defines second openings overlapping the first opening in a plan view, and
wherein the second layer includes silicon having a crystal orientation of <100>.

2. The mask of claim 1, wherein an angle formed between a surface of the deposition pattern, which is spaced apart from the first layer, and a side surface of the deposition pattern is about 45° or greater and about 75° or less.

3. The mask of claim 1, wherein a width of each of the second openings is greater than or equal to a thickness of the deposition pattern.

4. The mask of claim 1, wherein the first layer includes silicon.

5. The mask of claim 1, further comprising:
an insulating layer disposed between the first layer and the second layer.

6. A deposition apparatus comprising:
a deposition source which accommodates a deposition material;
a mask disposed on the deposition source, wherein the deposition material passes through the mask; and
a stage disposed on the mask, wherein a target substrate, on which the deposition material is to be deposited, is fixed to the stage,
wherein the mask includes:
a first layer defining a first opening; and
a second layer disposed on the first layer, wherein the second layer includes a deposition pattern having a reverse-tapered shape in a cross-sectional view,
wherein the deposition pattern defines second openings overlapping the first opening in a plan view, and
wherein the second layer includes silicon having a crystal orientation of <100>.

7. The deposition apparatus of claim 6, wherein an angle formed between a surface of the deposition pattern, which is spaced apart from the first layer, and a side surface of the deposition pattern is about 45° or greater and about 75° or less.

8. The deposition apparatus of claim 6, wherein a width of each of the second openings is greater than or equal to a thickness of the deposition pattern.

9. The deposition apparatus of claim 6, wherein the first layer includes silicon.

10. The deposition apparatus of claim 6, wherein the mask further includes an insulating layer disposed between the first layer and the second layer.

11. A method of manufacturing a mask, the method comprising:
forming a first layer defining a first opening by etching a preliminary first layer; and
forming a second layer including a deposition pattern having a reverse-tapered shape in a cross-sectional view by etching a preliminary second layer disposed below the preliminary first layer,
wherein the deposition pattern defines second openings overlapping the first opening in a plan view, and
wherein the second layer includes silicon having a crystal orientation of <100>.

12. The method of claim 11, wherein in the forming the second layer,
the deposition pattern is formed in a way such that a surface of the deposition pattern, which is spaced apart from the first layer, and a side surface of the deposition pattern form an angle of about 45° or greater and about 75° or less.

13. The method of claim 11, wherein in the forming the second layer,
a width of each of the second openings is formed to be greater than or equal to a thickness of the deposition pattern.

14. The method of claim 11, wherein in the forming the second layer,
the preliminary second layer is etched using an etchant including potassium hydroxide.

15. The method of claim 14, wherein a concentration of the potassium hydroxide is about 15 wt % or greater and about 70 wt % or less.

16. The method of claim 14, wherein a temperature of the potassium hydroxide is about 50° C. or higher and about 100° C. or lower.

17. The method of claim 11, wherein the forming the first layer includes:
forming an auxiliary pattern defining an auxiliary opening by etching the preliminary first layer.

18. The method of claim 17, wherein the forming the auxiliary pattern includes:
forming a first sub-opening by etching the preliminary first layer; and
forming second sub-openings connected to the first sub-opening by etching the preliminary first layer.

19. The method of claim 17, wherein in the forming the second layer,
the auxiliary pattern of the preliminary first layer and the preliminary second layer are etched simultaneously.

20. The method of claim 11, further comprising:
forming an insulating layer by etching a preliminary insulating layer disposed between the first preliminary layer and the second preliminary layer.
